(19) United States
(12) Patent Application Publication
(10) Pub. No.: US 2012/0202302 A1
(43) Pub. Date: Aug. 9, 2012

(54) SEMICONDUCTOR DEVICE MANUFACTURING SYSTEM AND METHOD FOR MANUFACTURING SEMICONDUCTOR DEVICE

(75) Inventors: Takashi Shimizu, Fishkill, NY (US); Hisashi Aikawa, Oita-ken (JP)

(73) Assignee: KABUSHIKI KAISHA TOSHIBA, Tokyo (JP)

(21) Appl. No.: 13/366,772

(22) Filed: Feb. 6, 2012

(30) Foreign Application Priority Data
Feb. 7, 2011 (JP) 2011-024000

(51) Int. Cl. H01L 21/66; G06F 19/00

(52) U.S. Cl. 438/14; 702/81; 257/E21.529

(57) ABSTRACT

Certain embodiments provide a semiconductor device manufacturing system including processing devices used in processing processes, a wafer transfer device, a processing characteristic measuring unit, a device characteristic measuring unit, data server, and an analysis server. The wafer transfer device conveys the wafer to the processing devices such that a direction of the wafer differs according to each processing process. The data server stores data. The data include processing characteristic data that is the processing characteristic of the wafer for each processing process measured by the processing characteristic measuring unit, the direction of the wafer for each processing process, and device characteristic data that is the device characteristic of the wafer measured by the device characteristic measuring unit. The analysis server specifies a cause process that causes the device characteristic data to be obtained based on the correlation between the processing characteristic data and the device characteristic data.

### CROSS REFERENCE TO RELATED APPLICATIONS

This application is based upon and claims the benefit of priority from the prior Japanese Patent Application No. 2011-024000 filed in Japan on Feb. 7, 2011; the entire contents of which are incorporated herein by reference.

### FIELD

Embodiments described herein relate generally to a semiconductor device manufacturing system and a method for manufacturing a semiconductor device.

### BACKGROUND

Semiconductor devices are manufactured by performing a wafer processing process such as a film forming process and an etching process. Processing characteristics of a wafer vary depending on a film thickness of a wafer, a dimension of a wafer, the shape of a wafer, and the like. The processing characteristics of a wafer also vary even with asymmetry of a chamber used in manufacturing equipment which is used to manufacture a semiconductor device. In a case where the processing characteristics of the wafer vary, a plurality of semiconductor devices manufactured from a single wafer would have different device characteristics. Regarding the manufactured semiconductor devices, when the device characteristics vary from device to device, there may be some semiconductor devices that do not satisfy the allowed characteristics. This lowers a fabrication yield. Generally, in manufacturing semiconductor devices, it is required to improve a fabrication yield.

In recent years, the number of processes of manufacturing a semiconductor device including a wafer processing process has reached hundreds to thousands. Of the processing processes, if a processing process is included in which the processing characteristic of the wafer (a wafer in-plane distribution of a normally processed area and an abnormally processed area) is not clearly shown, or if a plurality of processing processes are included which are similar to each other in the processing characteristic of the wafer, even viewing a device characteristic of a manufactured wafer (a wafer in-plane distribution of an area with a semiconductor device that satisfies an allowed device characteristic and an area with a semiconductor device that fails to satisfy an allowed device characteristic), it is difficult to specify a processing process that causes such a device characteristic of the wafer. Thus, it is difficult to specify the reason why a plurality of semiconductor devices manufactured from a single wafer have different device characteristic from each other.

### BRIEF DESCRIPTION OF THE DRAWINGS

FIG. 1 is a block diagram illustrating a semiconductor device manufacturing system according to a first embodiment.

FIG. 2 is an explanatory diagram describing a direction of a wafer.

FIGS. 3A and 3B are cross-sectional views of a FET, which illustrate various wafer processing processes for manufacturing the FET.

FIGS. 4A to 4C are cross-sectional views of a FET, which illustrate various wafer processing processes for manufacturing the FET.

FIGS. 5A and 5B are cross-sectional views of a FET, which illustrate various wafer processing processes for manufacturing the FET.

FIGS. 6A and 6B are cross-sectional views of a FET, which illustrate various wafer processing processes for manufacturing the FET.

FIG. 7 is a diagram illustrating a wafer in-plane distribution of a processing characteristic of each processing process.

FIGS. 8A and 8B are diagrams illustrating wafer in-plane distributions of actual processing characteristics after certain processing processes are performed.

FIG. 9 is a diagram illustrating a wafer in-plane distribution of a device characteristic.

FIG. 10 is a flowchart illustrating a method for specifying a cause process that causes a variation in device characteristic as a method for manufacturing a semiconductor device using the semiconductor device manufacturing system according to the first embodiment.

FIG. 11 is an explanatory diagram describing a method for setting a notch angle.

FIG. 12 illustrates a wafer in-plane distribution of a processing characteristic for each processing process when a notch is properly positioned.

FIGS. 13A to 13E are explanatory diagrams describing an example of a method for reducing a variation in a device characteristic.

FIG. 14 is a block diagram illustrating a semiconductor device manufacturing system according to a second embodiment.

FIG. 15 is a flowchart illustrating a method for specifying a cause process that causes a variation in a device characteristic as a method for manufacturing a semiconductor device using the semiconductor device manufacturing system according to the second embodiment.

### DETAILED DESCRIPTION

Certain embodiments provide a semiconductor device manufacturing system including a plurality of processing devices, a wafer transfer device, a processing characteristic measuring unit, a device characteristic measuring unit, a control server, a data server, and an analysis server. The plurality of processing devices are used in a plurality of processing processes for processing a wafer. The wafer transfer device sets a direction of the wafer differs according to each processing process and conveys the wafer to the plurality of processing devices. The processing characteristic measuring unit measures a processing characteristic of each in-plane position of the processed wafer each time when the wafer is processed in each processing process. The device characteristic measuring unit measures a device characteristic of each in-plane position of the wafer processed through the plurality of processing processes. The control server controls the plurality of processing devices, the wafer transfer device, the processing characteristic measuring unit, and the device characteristic measuring unit. The data server includes a database server that stores position/characteristic data including processing characteristic data that is the processing characteristic of each in-plane position of the wafer of each processing process, the direction of the wafer of each processing process, and device characteristic data that is the device characteristic of each in-plane position of the wafer. The analysis server obtains a correlation between the processing characteristic data of each processing process and the device characteristic data based on the position/characteristic data, and specifies a cause process that causes the device characteristic data to be obtained based on the correlation.

Certain embodiments provide a method for manufacturing a semiconductor device including setting a direction of a wafer, storing the set direction of the wafer, measuring a processing characteristic of each in-plane position of the wafer, measuring a device characteristic of each in-plane position of the wafer, obtaining a correlation between processing characteristic data of each processing process and device characteristic data, and specifying a cause process. The direction of the wafer is set to differ according to each processing process. The processing characteristic of each in-plane position of the wafer is measured after the wafer is processed in the set direction of the wafer. The device characteristic of each in-plane position of the wafer is measured after the wafer is processed through a plurality of processing processes. The correlation is obtained based on position/characteristic data including the processing characteristic data that is a processing characteristic of each in-plane position of the wafer of each processing process, the direction of the wafer of each processing process, and the device characteristic data that is a device characteristic of each in-plane position of the wafer. The cause process is specified based on the correlation.

Hereinafter, a semiconductor device manufacturing system and a method for manufacturing a semiconductor device according to exemplary embodiments will be described.

### First Embodiment

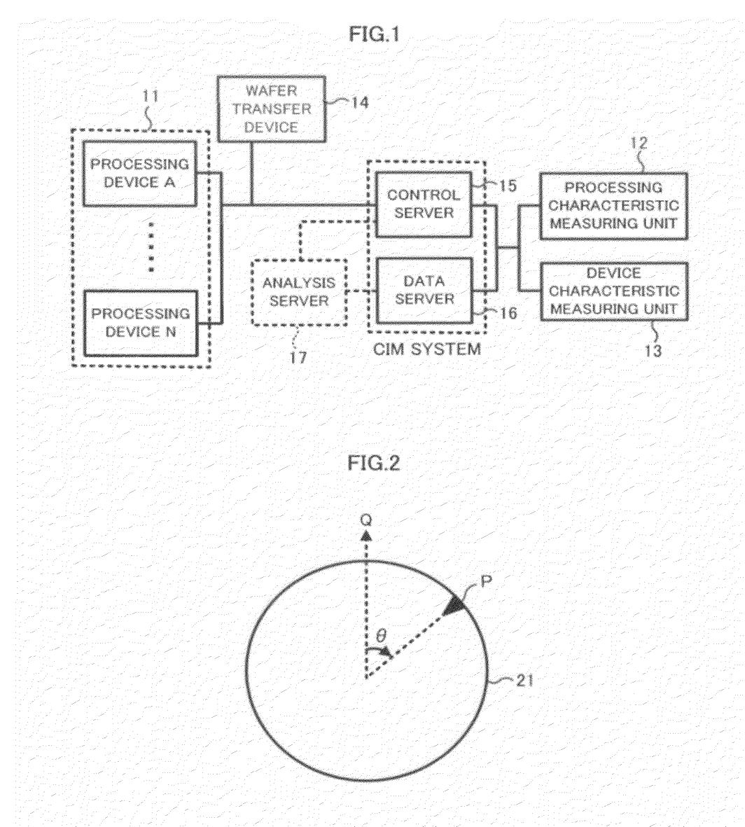

FIG. 1 is a block diagram illustrating a semiconductor device manufacturing system according to the present embodiment. The present system includes a processing device 11, a processing characteristic measuring unit 12, and a device characteristic measuring unit 13.

The processing device 11 includes a plurality of processing devices (processing devices A to N) that perform processing processes, such as a film forming process, a heating process, and an etching process, on a wafer.

The processing characteristic measuring unit 12 is configured with a device that measures the processing characteristic of each in-plane position of the wafer processed by each processing process. Here, the processing characteristic means, for example, a film thickness of a film formed on a processed wafer, resistance of a wafer, resistance of a film formed on a wafer, a dimension of a processed wafer, the shape of a processed wafer, and the like.

The device characteristic measuring unit 13 is configured with a device that measures the device characteristic such as a threshold voltage of each in-plane position (chip) of a wafer, a yield, and the like after a device is formed.

The semiconductor device manufacturing system further includes a wafer transfer device 14 that sorts wafers and conveys the wafers to the processing device 11 in a state in which the wafers are headed in a predetermined direction.

Typically, a V-shaped notch portion (hereinafter, the V-shaped notch portion is referred to as “notch”) is formed on the periphery of a wafer as a reference mark for recognizing a direction of a wafer.

FIG. 2 is an explanatory diagram for describing a direction of a wafer. For example, when a notch angle θ is set as a direction of a wafer with respect to the processing device 11, the wafer transfer device 14 conveys a wafer 21 to the processing device in a state in which a notch P formed in the wafer 21 is positioned at the position at which the wafer 21 is rotated an angle of θ from a conveyance direction (a direction of an arrow Q in FIG. 2) of the wafer 21 as illustrated in FIG. 2.

In the semiconductor device manufacturing system, the processing characteristic measuring unit 12 and the device characteristic measuring unit 13 are connected to the processing device 11 through a computer integrated manufacturing (CIM) system. The wafer transfer device 14 is also connected to the CIM system.

The CIM system includes a control server 15 and a data server 16.

The control server 15 controls the processing device 11, the processing characteristic measuring unit 12, the device characteristic measuring unit 13, the wafer transfer device 14, and the like.

The data server 16 stores position/characteristic data such as a measurement result of the processing characteristic measuring unit 12 and a measurement result of the device characteristic measuring unit 13 and a notch angle, and information such as a typical lot number and a wafer number.

The semiconductor device manufacturing system may further include an analysis server 17. When the present system includes the analysis server 17, the server 17 is connected to the control server 15 and the data server 16.

The analysis server 17 obtains a correlation between the wafer in-plane distribution of the device characteristic and the wafer in-plane distribution of the processing characteristic of each processing process, which will be described later, based on the position/characteristic data stored in the data server 16, and then specifies a cause process that causes the wafer in-plane distribution of a device characteristic to be obtained, based on the obtained correlation.

In a process of manufacturing a semiconductor device, the cause process that causes a variation in the device characteristic is specified as follows using the above described semiconductor device manufacturing system.

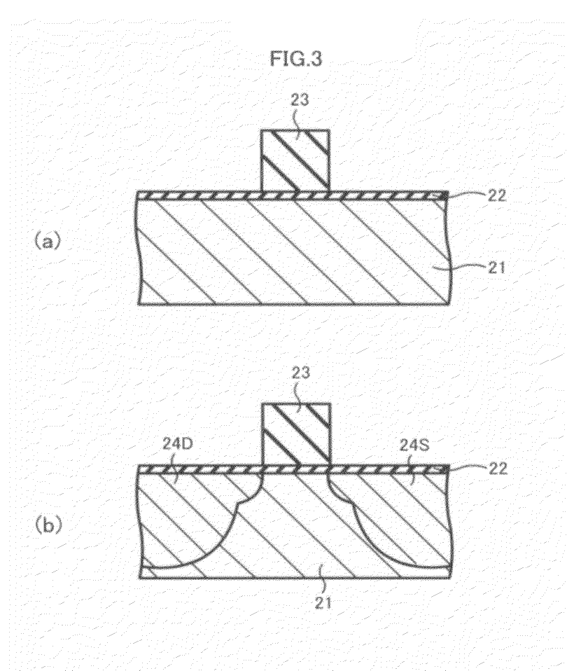

Here, it is assumed that each of a plurality of semiconductor devices manufactured on a wafer is, for example, a field effect transistor (FET). Further, it is assumed that a wafer is processed as follows in order to manufacture a FET. FIGS. 3A to 6B are cross-sectional views of a FET, which illustrate various wafer processing processes for manufacturing a FET.

First, an oxide film 22, which will become a gate insulating film, is formed on a surface of the wafer 21, and a resist mask 23 for forming a doped region which will become a drain and a source is formed (FIG. 3(a)) on the oxide film 22. Subsequently, impurities are implanted into the wafer 21 using the resist mask 23 (FIG. 3(b)). As a result, a drain 24D and a source 24S are formed.

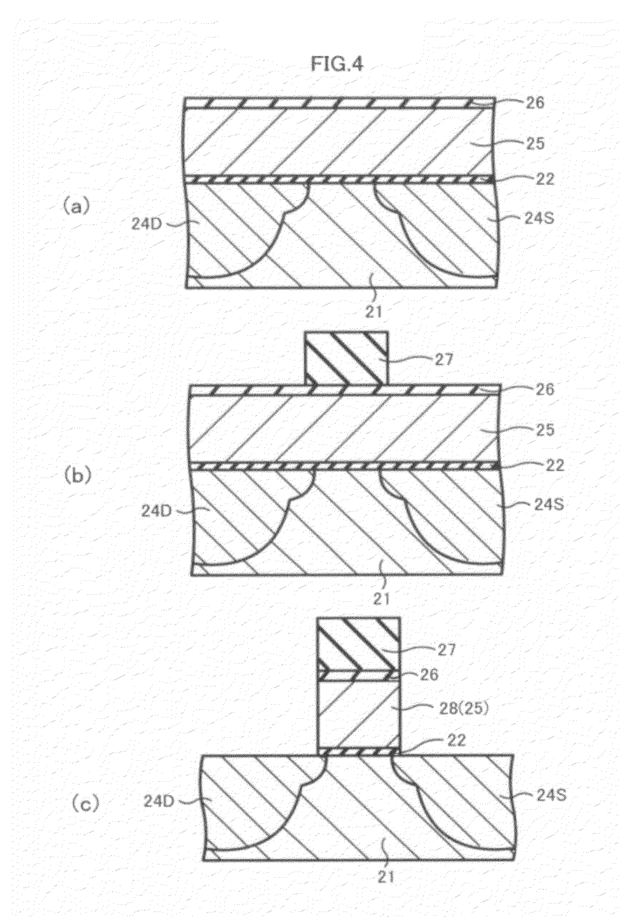

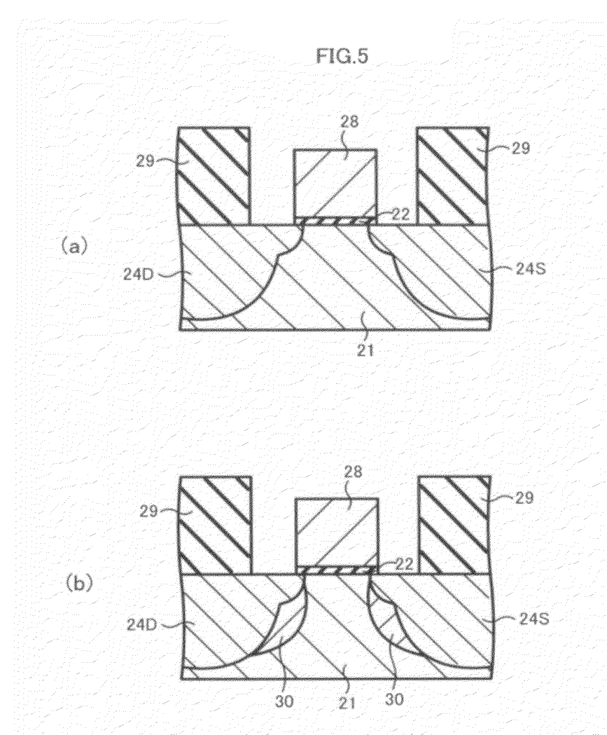

Next, a polysilicon film 25 and an anti-reflection film 26 are sequentially formed over the wafer 21 (FIG. 4(a)), and a resist mask 27 for forming a gate electrode is formed on the anti-reflection film 26 (FIG. 4(b)). Subsequently, the polysilicon film 25 and the anti-reflection film 26 are etched using the resist mask 27 using a reactive ion etching (RIE) technique (FIG. 4(c)). As a result, the gate electrode 28 is formed.

After removing the resist mask 27, a resist mask 29 for forming an impurity layer having a conductive type opposite to the drain 24D and the source 24S is formed over the wafer 21 (FIG. 5(a)), and impurities are implanted into the wafer 21 using the resist mask 29 (halo implantation) (FIG. 5(b)). As a result, an impurity layer 30 having a conductive type opposite to the drain 24D and the source 24S is formed. The impurity layer 30 prevents the drain 24D and the source 24S from coming into contact with each other as the drain 24D and the source 24S are thermally diffused.

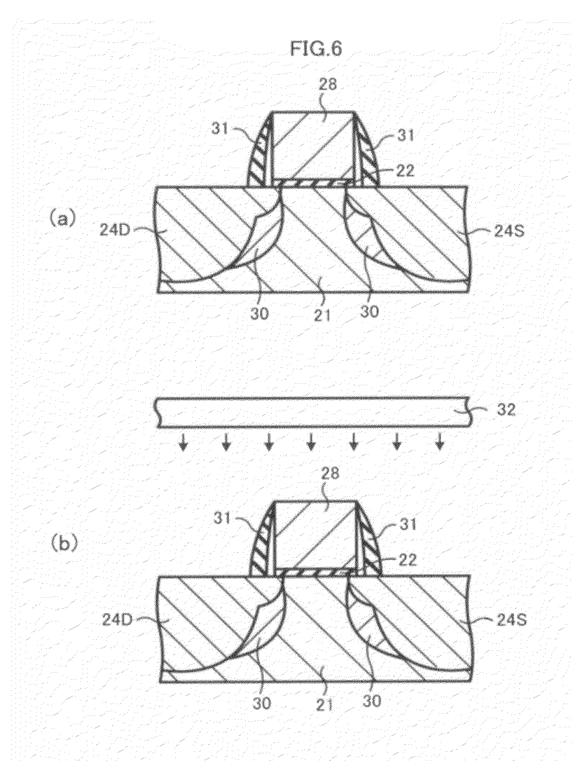

After removing the resist mask 29, a gate sidewall 31 is formed on the gate electrode 28 (FIG. 6(a)), and an annealing process is performed using a lamp 32 which is a heat source (spike rapid thermal annealing (RTA)) (FIG. 6(b)). For example, the gate sidewall 31 is formed such that a predetermined gap is formed between the side surface of the gate electrode 28 and the gate sidewall 31 as illustrated in FIG. 6(a).

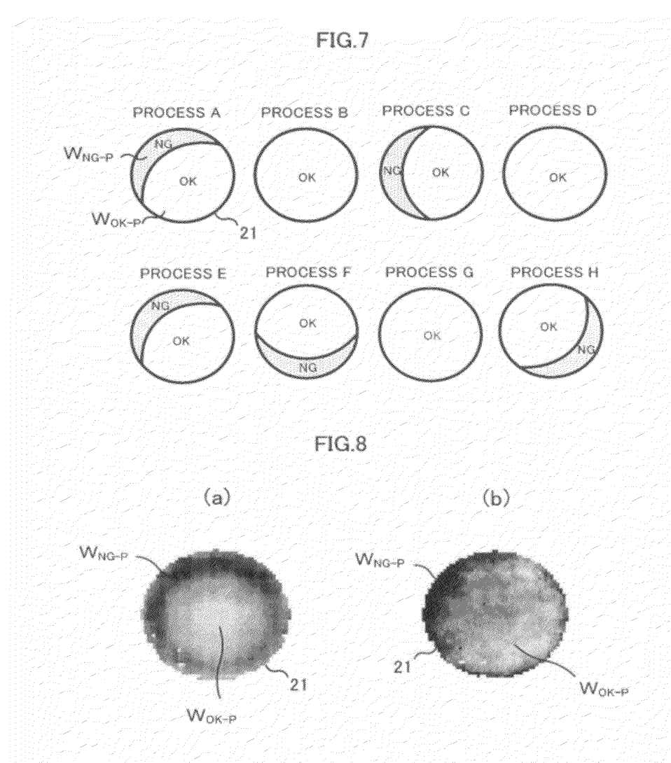

The processes of FIGS. 3(a) to 6(a) are referred to processing processes A to H, respectively. FIG. 7 is a diagram illustrating the processing characteristics of the wafer 21 in the processing processes A to H. The processing characteristics of the processing processes A to H are different from one another as illustrated in FIG. 7. That is, in the wafer 21 processed by the processes A to H, a normally processed area and an abnormally processed area are distributed in the surface of the wafer 21 as illustrated in FIG. 7 (here, an notch angle is randomly set). In FIG. 7, an area W_{OK-P} indicated by OK means the normally processed area, and an area W_{NG-P} indicated by NG means the abnormally processed area.

In the following description, the distribution in the surface of the wafer 21 of the normally processed area W_{OK-P} and the abnormally processed area W_{NG-P} is referred to the wafer in-plane distribution of the processing characteristic.

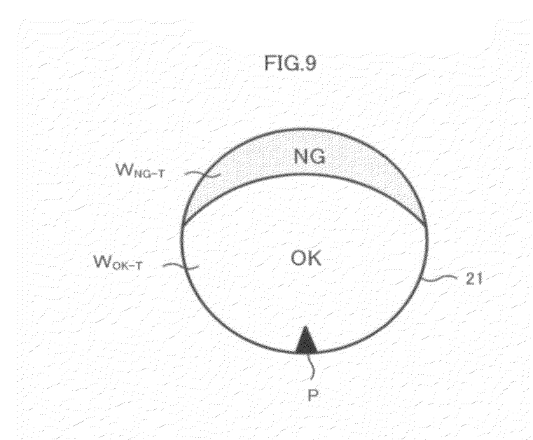

In the wafer in-plane distribution of the processing characteristic in the processing processes A to H, the shape and position of the area W_{NG-P} differ according to the thickness of the wafer 21, a dimension of the wafer 21, the shape of the wafer 21, and the like. In addition, the shape and position of the area W_{NG-P} differ according to the asymmetry of a chamber of a processing device used in the processing processes A to H. FIGS. 8A and 8B illustrate the wafer in-plane distributions of actual processing characteristics after certain processing processes are performed. As illustrated in FIGS. 8A and 8B, the area W_{NG-P} may look like a crescent moon at an eccentric position but is not limited thereto. For example, the area W_{NG-P} may look like a half moon, or the area W_{NG-P} may be scattered in the surface of the wafer.

The processing characteristic differs according to each processing process. The processing characteristic means the sizes of various resist masks, gate electrodes, gate sidewalls, and the like, and dose amounts of various impurity layers and the like.

The device characteristic of each FET (hereinafter, the FET is referred to as “chip”) formed on the wafer (manufactured wafer) 21 processed by the various processing processes described above means, for example, a threshold voltage of the gate electrode.

FIG. 9 is a diagram illustrating a device characteristic of a wafer. Threshold voltages of chips formed on the processed wafer 21 are different from one another as illustrated in FIG. 9. That is, as to the processed wafer 21, chips that satisfy an allowable threshold characteristic and chips that do not satisfy an allowable threshold characteristic are distributed in the surface of the wafer 21 as illustrated in FIG. 9. In FIG. 9, an area W_{OK-T} indicated by OK represents an area where chips having a threshold voltage within an allowable range are manufactured. Further, In FIG. 9, an area W_{NG-T} indicated by NG represents an area where chips having a threshold voltage outside an allowable range are manufactured.

In the following description, a wafer in-plane distribution of chips that satisfy an allowable threshold characteristic and chips that do not satisfy an allowable threshold characteristic is referred to as a wafer in-plane distribution of a threshold voltage.

In the wafer in-plane distribution of the device characteristic such as the wafer in-plane distribution of the threshold voltage, as illustrated in FIG. 9, the area W_{NG-T} may look like a crescent moon at an eccentric position but is not limited thereto. For example, the area W_{NG-T} may look like a half moon, or the area W_{NG-T} may be scattered in the surface of the wafer.

As described above, the processing processes A to H are defined as a full processing process (front end process) for manufacturing a chip (FET). However, when a processing process that affects the device characteristic (for example, a processing process that affects a threshold voltage characteristic) is known in advance, the processing processes A to H may be defined as a processing process that affects the device characteristic.

The threshold voltage characteristic of the gate electrode is affected, for example, by a gate length, the size of a gate sidewall, and a channel length. Thus, when the processing processes A to H are processing processes that affect the threshold voltage characteristic, the processing processes A to H include, for example, processes for forming the gate electrode, a process for forming the gate sidewall, and a process for forming an impurity layer having a conductive type opposite to a drain and a source.

Next, a description will be made in connection with a method for specifying a cause process that causes a variation in the device characteristic using a case in which there is a possibility that any one of the processing processes A to H illustrated in FIG. 7 will affect a threshold voltage of a manufactured chip, and as a result, a wafer having the in-plane distribution of the threshold voltage illustrated in FIG. 9 is manufactured as an example.

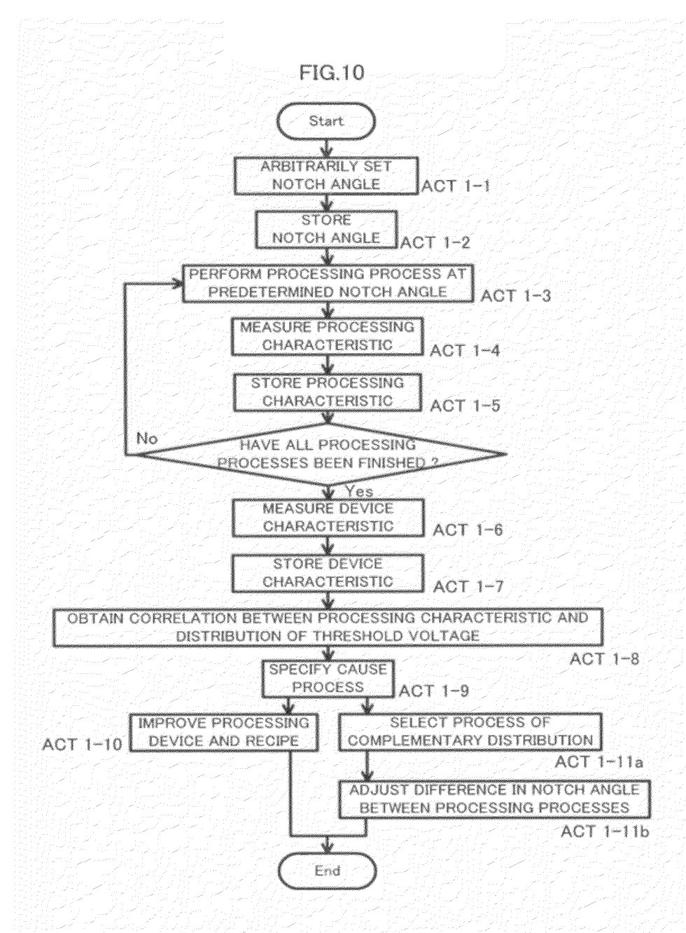

FIG. 10 is a flowchart illustrating a method for specifying a cause process that causes a variation in a device characteristic as a method for manufacturing a semiconductor device using the semiconductor device manufacturing system according to the first embodiment.

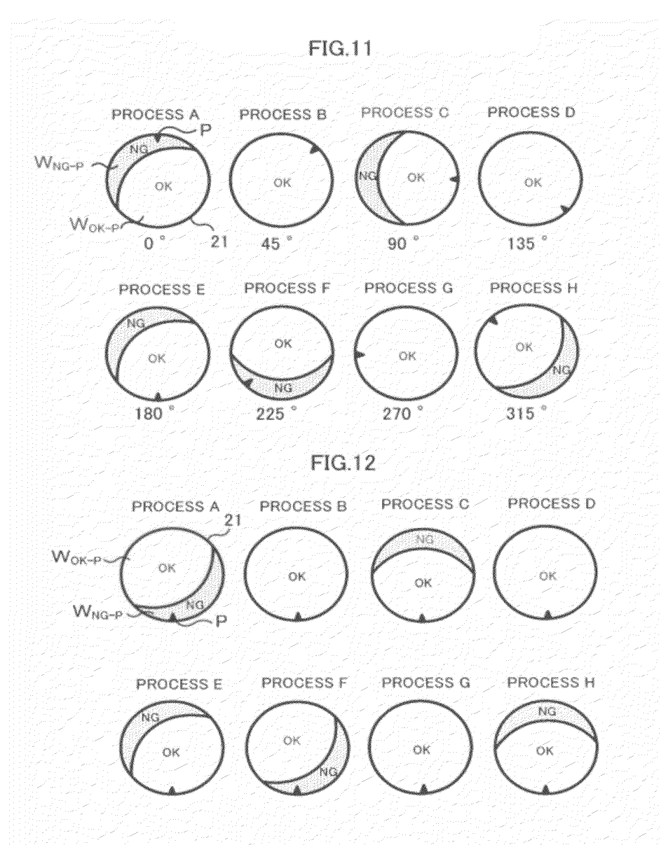

As illustrated in FIG. 5, first, the control server 15 arbitrarily sets a direction of a wafer so that a direction of a wafer can differ according to each of the processing processes A to H (ACT 1-1). FIG. 11 is an explanatory diagram for describing a method for setting a notch angle. As illustrated in FIG. 11, when a notch angle is set as a direction of a wafer, different notch angles are set within a range of 0° to 315° for each of the processing processes A to H so that a difference in the notch angle of the notch P between the processing processes A to H can be 45°.

The following description will be made in connection with an example in which the notch angle is set as the direction of the wafer.

Next, the data server 16 stores the set notch angles of the processing processes A to H in a database (ACT 1-2).

The wafer transfer device 14 aligns each wafer according to the notch angle stored in the database and then stores each wafer in a front opening unified pod (FOUP) (a conveyance container used for storing and conveying wafers). For example, as illustrated in FIG. 11, when the notch angle is set to 0° for the processing process A, the wafer transfer device 14 aligns each wafer so that the notch angle of each wafer can be 0°, and then stores each wafer in a FOUP (a conveyance container used for storing and conveying wafers).

Next, each aligned wafer is conveyed to the processing device 11A used in the processing process A, and a processing process “a” is performed (ACT 1-3). For example, each wafer is conveyed to the processing device 11A in a state in which the notch angle is 0°, and the processing process “a” is performed.

Next, the processing characteristic measuring unit 12 measures a processing characteristic “a” of each in-plane position of the wafer in the wafer which has been subjected to the processing process a (ACT 1-4). Then, the data server 16 stores a measurement result in a database (ACT 1-5).

Next, the same process as in the processing process A is performed on the remaining processing processes B to H. That is, each wafer is conveyed to the processing device so that the notch angle of each wafer can be an angle set for each of the processing processes B to H, and then processing processes b to h are performed (ACT 1-3). The processing characteristic measuring unit 12 measures processing characteristics b to h for each in-plane position of the wafer (ACT 1-4). The data server 16 stores the in-plane distribution of the measured processing characteristics b to h in a database (ACT 1-5).

When all processing processes are completed, the device characteristic measuring unit 13 measures a threshold voltage of each in-plane position (for each chip) of the wafer (ACT 1-6). Then, threshold voltage data (the wafer in-plane distribution of the threshold voltage) of each in-plane position of the wafer, which is obtained by a measurement result, is stored in a database in the database server 16 as position/characteristic data together with the notch angle set for each of the processing processes A to H and processing characteristic data of the processing processes A to H (the wafer in-plane distributions of the processing characteristics a to h) (ACT 1-7).

Next, a correlation between the wafer in-plane distribution of the threshold voltage and the wafer in-plane distribution of the processing characteristic of each of the processing processes A to H is obtained based on the stored position/characteristic data (ACT 1-8). The correlation may be obtained as described below.

FIG. 12 illustrates the wafer in-plane distribution of the processing characteristic of each of the processing processes A to H when the position of the notch P is aligned. When the wafer in-plane distribution of the processing characteristic in which the position of the notch P is aligned as illustrated in FIG. 12 is compared to the wafer in-plane distribution of the threshold voltage illustrated in FIG. 9, it can be understood that a correlation between the in-plane distribution of the threshold voltage illustrated in FIG. 9 and the wafer in-plane distribution of the processing characteristic of the processing process C is high.

The correlation between the wafer in-plane distribution of the threshold voltage and the wafer in-plane distribution of the processing characteristic of each of the processing processes A to H may be obtained, based on the stored position/characteristic data, by a user of the system according to the present invention or the like, or may be automatically obtained by the analysis server 17. When the correlation is obtained by the user of the system according to the present invention or the like, the analysis server 17 may not be necessary.

In the processed wafer, the wafer in-plane distribution of the threshold voltage is compared with the wafer in-plane distribution of the processing characteristic of each processing process. A process that is high in the correlation with the wafer in-plane distribution of the threshold voltage is recognized as the cause process that causes the variation in the device characteristic. For example, when the wafer in-plane distribution of the threshold voltage in the processed wafer has the distribution illustrated in FIG. 9, the processing process C is specified as a process that causes chips to have different threshold voltages (ACT 1-9).

The wafer in-plane distribution of the processing characteristic mostly has a characteristic distribution specific to the processing device used in the processing process. For this reason, an improvement in the processing device such as gradient adjustment of the wafer is made in the processing process C specified as the cause process so as to suppress the variation in the wafer in-plane processing characteristic (ACT 1-10).

Alternatively, an improvement in a processing recipe such as a processing sequence or a processing condition is made in the processing process C specified as the cause process. In this case, the variation in the wafer in-plane processing characteristic can be suppressed.

In addition, when the processing process specified as the cause process is the process C, a processing recipe such as a processing sequence or a processing condition may be adjusted in any one of the subsequent processes D to H.

For example, when the processing process C is a process of forming the resist mask for forming the gate electrode, an etching time may be adjusted in an etching process which is a processing process subsequent thereto. That is, when the resist mask is formed to have a size larger than a designed size, an etching time may be adjusted to be longer than a designed time, whereas when the resist mask is formed to have a size smaller than a designed size, an etching time may be adjusted to be shorter than a designed time.

Furthermore, the variation in the device characteristic such as the variation in the threshold voltage also can be reduced such that after the cause process is specified in ACT 1-9, a processing process having a complementary processing characteristic to the processing characteristic in the specified processing process is selected as necessary (ACT 1-11a), and a notch angle difference between the processing processes is adjusted to cancel the variation in the processing characteristic (ACT 1-11b).

FIGS. 13A to 13E are explanatory diagrams for describing an example of a method of reducing the variation in the device characteristic. For example, the description will be made assuming that there are a process in which a wafer in-plane distribution of a processing characteristic as illustrated in FIG. 13A is obtained and a process in which a wafer in-plane distribution of a processing characteristic as illustrated in FIG. 13B is obtained. If the positions of the notches P are set to be in the same position, a wafer in-plane device characteristic (threshold voltage) illustrated in FIG. 13C is finally obtained. In FIG. 13C, a horizontal axis denotes a value of a threshold voltage Vth, and a vertical axis denotes the number of chips.

However, as illustrated in FIG. 13D, when the position of the notch is adjusted to rotate 180° with respect to the position of the notch P illustrated in FIG. 13B, a wafer in-plane device characteristic (threshold voltage) illustrated in FIG. 13E is finally obtained. Comparing FIG. 13C with FIG. 13E, it can be understood that a variation Wₜₕ₋ₑ in a threshold voltage illustrated in FIG. 13E is smaller than a variation W_{th-c} in a threshold voltage illustrated in FIG. 13C.

By adjusting the difference in the notch angle in the above-described way, the variation in the device characteristic such as the variation in the threshold voltage also can be reduced.

In the above-described way, the variation in the threshold voltage that is attributable to the variation in the wafer in-plane processing characteristic in the cause process can be suppressed.

Further, when there are processes that are expected to have similar device characteristic variations in advance, the notch angle is set in the process (ACT 1-1) of setting the notch angle to increase the difference in the notch angles between the processes. Through such setting, the cause process can be more easily specified.

That is, the wafer in-plane distribution of the processing characteristic of each processing process becomes approximately constant, regardless of the position of the notch. For example, when it is expected that the wafer in-plane distributions of the processing characteristic are approximate to each other like the wafer in-plane distribution of the processing characteristic in the process A and the wafer in-plane distribution of the processing characteristic in the process E, which are illustrated in FIG. 7, the notch angle is set in the process (ACT 1-1) of setting the notch angle to increase the difference between the notch angle in the process A and the notch angle in the process E. When the notch angle is set as described above, the position of the notch P of the NG area in the processing process A is significantly different from that in the processing process E even though it is expected that the wafer in-plane distributions (for example, the positions of the NG area) of the processing characteristic in different processing processes are approximate to each other. Thus, the cause process can be more easily specified.

In the present embodiment, the threshold voltage is given as an example of the device characteristic correlated with the processing characteristic. However, the device characteristic correlated with the processing characteristic is not limited to the threshold voltage. For example, a gate leak current, a drain current, gate insulating film capacity, resistance, and the like may be given as another example of the device characteristic correlated with the processing characteristic.

According to the present embodiment, in the process of manufacturing the semiconductor device, the notch angle is set to differ according to each processing process, and the set notch angle is stored. Next, the position of the notch is aligned, and then the cause process that causes the variation in the device characteristic can be specified based on a correlation between the wafer in-plane distribution of the device characteristic such as the threshold voltage and the wafer in-plane distribution of each processing characteristic. Then, by suppressing influence of the variation in the processing characteristic in the cause process, the variation in the device characteristic can be suppressed, and thus the yield can be improved.

### Second Embodiment

The present embodiment is the same in configuration as the first embodiment but different from the first embodiment in a method for setting a notch angle. Further, the present embodiment is different from the first embodiment in that the analysis server analyzes the correlation between the wafer in-plane distribution of the processing characteristic and the wafer in-plane distribution of the device characteristic using a correlation coefficient.

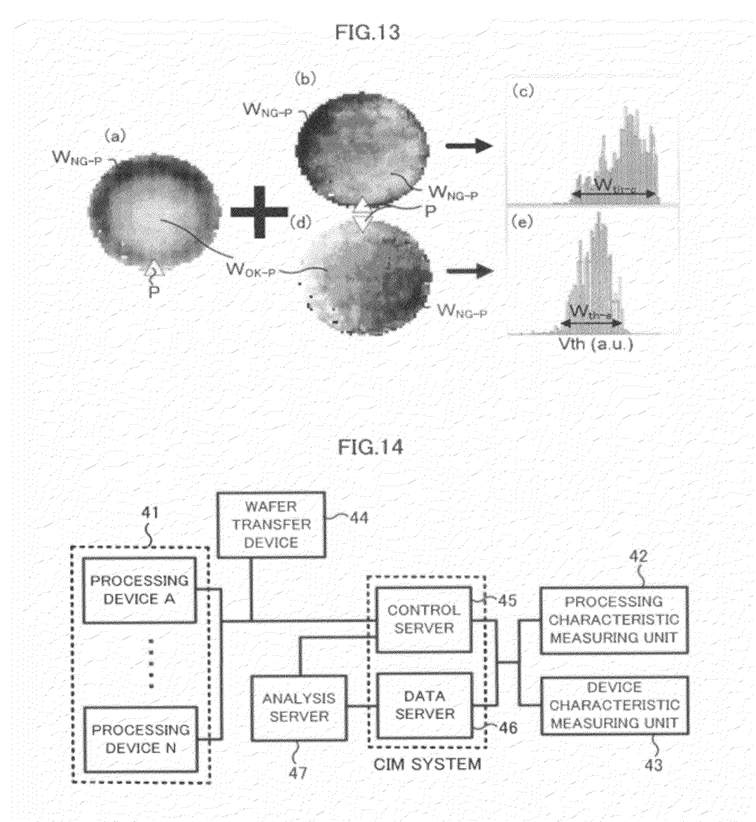

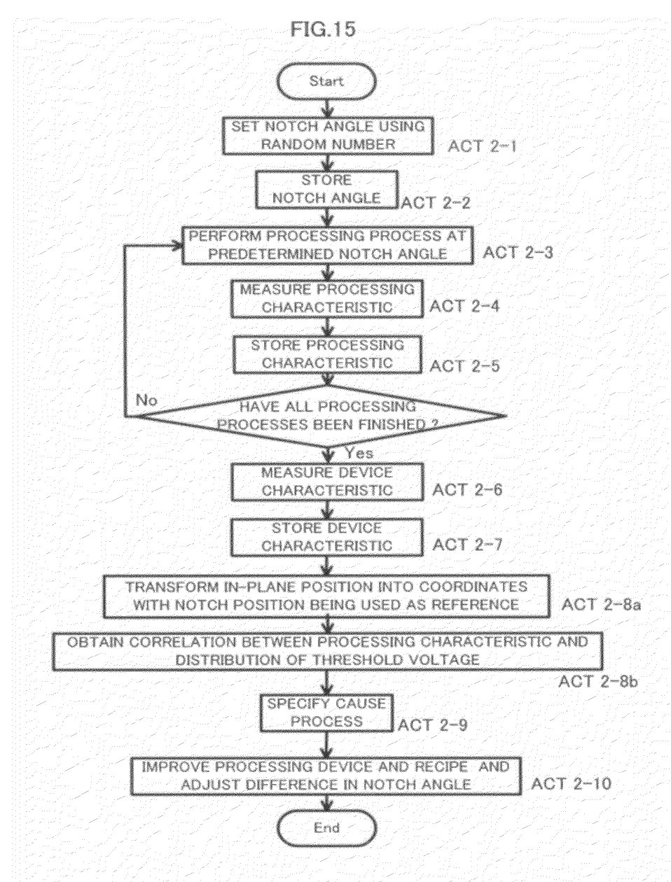

FIG. 14 is a block diagram illustrating a semiconductor device manufacturing system according to the present embodiment. The present system includes a processing device 21 that performs a processing process, a processing characteristic measuring unit 22, and a device characteristic measuring unit 23, similarly to the first embodiment. Further, a wafer transfer device 24 is arranged.

The semiconductor device manufacturing system according to the present embodiment controls the processing device 21, the processing characteristic measuring unit 22, the device characteristic measuring unit 23, and the wafer transfer device 24. The semiconductor device manufacturing system according to the present embodiment further includes a CIM system that is configured with a control server 25 that generates a notch angle in each processing process and a data server 26 that includes a database for storing position/characteristic data. In addition, the semiconductor device manufacturing system according to the present embodiment further includes an analysis server 27 that performs analysis based on the position/characteristic data.

The cause process that causes the variation in the device characteristic in the process of manufacturing the semiconductor device is specified using the semiconductor device manufacturing system as follows.

FIG. 15 is a flowchart illustrating a method for specifying the cause process that causes the variation in a device characteristic as a method for manufacturing a semiconductor device using the semiconductor device manufacturing system according to the second embodiment.

As illustrated in FIG. 15, first, the control server 45 of the CIM system sets a direction of a wafer with respect to the processing device 41 using an automatically generated random number of 0 to 360 so that a direction of a wafer can differ according to each of the processing processes (ACT 2-1).

The following description will be made in connection with an example in which the notch angle is set as the direction of the wafer.

Next, the data server 46 stores the set notch angles of the processing processes A to H in a database (ACT 2-2).

The notch angle of each processing process may be set using a random number automatically generated in the processing device 41 or the wafer transfer device 44. In this case, the notch angle set for each processing process is stored in a database in the data server 46 on the CIM system at each time.

Then, similarly to the first embodiment, the wafer is aligned at the notch angle set for each processing process, and then each processing device performs each processing process (ACT 2-3). Subsequently, the processing characteristic measuring unit 42 measures a processing characteristic of each in-plane position of the wafer (ACT 2-4). Then, the data server 46 on the CIM system stores a measurement result in a database (ACT 2-5).

When all processing processes are completed, the device characteristic measuring unit 43 measures a threshold voltage of each in-plane position (for each chip) of the wafer (ACT 2-6). Then, threshold voltage data (the wafer in-plane distribution of the threshold voltage) of each in-plane position of the wafer, which is obtained by a measurement result, is stored in a database in the database server 46 as position/characteristic data together with the notch angle set for each of the processing processes A to H and processing characteristic data of the processing processes A to H (the wafer in-plane distributions of the processing characteristics a to h) (ACT 2-7).

Next, the analysis server 47 transforms the wafer in-plane position of each chip into coordinates based on the stored position/characteristic data (ACT 2-8a). The position of each chip is transformed based on the position of the notch. Subsequently, a correlation coefficient between the wafer in-plane distribution of the threshold voltage and the wafer in-plane distribution of the processing characteristic of each processing process is obtained (ACT 2-8b). A cause process is specified according to the rankings of the correlation coefficients on the in-plane distribution of the threshold voltage (ACT 2-9).

A description will be concretely made with reference to FIG. 12. The rankings of the correlation coefficients on the in-plane distribution of the threshold voltage illustrated in FIG. 9 are in the order of the process C, (the process E+the process H), (the process A+the process F), and (the process B+the process D+the process G) from the top. Thus, the process C is specified as the cause process having the in-plane distribution of the threshold voltage illustrated in FIG. 9.

Next, an improvement in the processing device, an improvement in a processing recipe such as the processing sequence or the processing condition, or adjustment of the difference in the notch angle for the processing process is made in the processing process C specified as the cause process so as to suppress the variation in the wafer in-plane processing characteristic (ACT 2-10).

In the present embodiment, the notch angle is set to differ according to each processing process, and the set notch angle is stored. Next, the position of the notch is aligned, and then the cause process that causes the variation in the device characteristic can be specified based on the correlation between the wafer in-plane distribution of the device characteristic such as the threshold voltage and the wafer in-plane distribution of each processing characteristic. Then, by suppressing influence of the variation in the processing characteristic in the cause process, the variation in the device characteristic can be suppressed, and thus the yield can be improved.

Further, according to the present embodiment, the notch angle can be automatically set, and the correlation coefficient between the wafer in-plane distribution of the device characteristic and the wafer in-plane distribution of each processing characteristic can be automatically obtained. Thus, the cause process that causes the variation in the device characteristic can be more easily specified.

In the first and second embodiments, the notch angle is set to differ according to each processing process, and the notch angle may be set to differ according to each wafer in a processing lot. Since the notch angle is set to differ according to each wafer as well as the processing process as described above, even when there is a possibility that the variation in the device characteristic will be caused in many processing processes, the accuracy of specifying the cause process can be improved.

Further, in the first and second embodiments, specific processing processes are selected, and then the cause process is specified from among the selected processing processes. However, when a possible processing process is selected in advance, the speed and accuracy of specifying the cause process can be improved. However, selection of the processing process needs not be necessarily performed, and the cause process can be specified from among all processing processes.

According to the semiconductor device manufacturing system and the method for manufacturing the semiconductor device of at least one of the above described embodiments, the process that affects the variation in the device characteristic in the process of manufacturing the semiconductor device can be specified. Thus, the variation in the device characteristic can be suppressed, and the yield can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the above embodiments, the V-shaped notch portion (notch) formed by cutting away part of the periphery of a wafer in the shape of a character V is used as the reference mark for recognizing the direction of the wafer. However, in the present embodiment, the reference mark is not limited to the notch. For example, a notch portion of a straight line shape (an orientation flat) formed by cutting away part of the periphery of a wafer in the shape of a straight line may be used as the reference mark.

What is claimed is:

1. A semiconductor device manufacturing system, comprising:
a plurality of processing devices that are used in a plurality of processing processes employed to process a wafer;
a wafer transfer device that sets a direction of the wafer to differ according to each processing process and conveys the wafer to the plurality of processing devices;
a processing characteristic measuring unit that measures a processing characteristic of each in-plane position within the processed wafer each time the wafer is processed with each processing process;
a device characteristic measuring unit that measures a device characteristic of each in-plane position within the wafer processed through the plurality of processing processes;
a control server that controls the plurality of processing devices, the wafer transfer device, the processing characteristic measuring unit, and the device characteristic measuring unit;
a data server that stores position/characteristic data including processing characteristic data that is the processing characteristic of each in-plane position within the wafer for each processing process, the direction of the wafer for each processing process, and device characteristic data that is the device characteristic of each in-plane position within the wafer; and
an analysis server that obtains a correlation between the processing characteristic data of each processing process and the device characteristic data based on the position/characteristic data, and specifies a cause process that causes the device characteristic data to be obtained based on the correlation.

2. The semiconductor device manufacturing system according to claim 1,
wherein the analysis server obtains the correlation between the processing characteristic data of each processing process and the device characteristic data, after the processing characteristic data of each processing process is aligned in a manner that the directions of the wafer for the respective processing process represent one direction.

3. The semiconductor device manufacturing system according to claim 1,
wherein the analysis server specifies the processing process in which the processing characteristic data having the highest correlation with the device characteristic data is obtained as the cause process.

4. The semiconductor device manufacturing system according to claim 1,
wherein the analysis server estimates correlation rankings from the correlation between the processing characteristic data of each processing process and the device characteristic data, and specifies the cause process that causes the device characteristic data to be obtained based on the correlation rankings.

5. The semiconductor device manufacturing system according to claim 4,
wherein the analysis server specifies the processing process in which the processing characteristic data having a highest correlation coefficient with respect to the device characteristic data is obtained as the cause process.

6. The semiconductor device manufacturing system according to claim 1,
wherein the directions of the wafers are set to differ according to each wafer included in a processing lot in the processing process.

7. The semiconductor device manufacturing system according to claim 1,
wherein the wafer includes a notch used to recognize the direction of the wafer, and
the direction of the wafer is a notch angle.

8. The semiconductor device manufacturing system according to claim 7,
wherein the notch angle of each processing process is set to be shifted by a constant angle from that of another processing process.

9. The semiconductor device manufacturing system according to claim 7,
wherein the notch angles of the respective processing processes are randomly set for each processing process.

10. The semiconductor device manufacturing system according to claim 9,
wherein the notch angles of the respective processing processes are randomly set for each processing process using a random number from 0 to 360.

11. A method for manufacturing a semiconductor device, comprising:
setting a direction of a wafer to differ according to each processing process;
storing the set direction of the wafer;
measuring a processing characteristic of each in-plane position within the wafer after processing the wafer that faces the set direction of the wafer;
measuring a device characteristic of each in-plane position within the wafer that has passed through a plurality of processing processes;
obtaining a correlation between processing characteristic data of each processing process and device characteristic data based on position/characteristic data including the processing characteristic data that is a processing characteristic of each in-plane position within the wafer for each processing process, the direction of the wafer for each processing process, and the device characteristic data that is a device characteristic of each in-plane position within the wafer; and
specifying a cause process that causes the device characteristic data to be obtained based on the correlation.

12. The method for manufacturing a semiconductor device according to claim 11,
wherein the correlation is obtained after the processing characteristic data of each processing process is aligned in a manner that the directions of the wafer for the respective processes represent one direction.

13. The method for manufacturing a semiconductor device according to claim 11,
wherein the processing process, in which the processing characteristic data having the highest correlation with the device characteristic data is obtained, is specified as the cause process.

14. The method for manufacturing a semiconductor device according to claim 11, further comprising:
estimating correlation rankings from the correlation between the processing characteristic data of each processing process and the device characteristic data; and
specifying the cause process that causes the device characteristic data to be obtained based on the correlation rankings.

15. The method for manufacturing a semiconductor device according to claim 14,
wherein the processing process, in which the processing characteristic data having a highest correlation coefficient with respect to the device characteristic data, is obtained is specified as the cause process.

16. The method for manufacturing a semiconductor device according to claim 11,
wherein the directions of the wafers are set to differ according to each wafer included in a processing lot in the processing process.

17. The method for manufacturing a semiconductor device according to claim 11,
wherein the wafer includes a notch used to recognize the direction of the wafer, and
the direction of the wafer is a notch angle.

18. The method for manufacturing a semiconductor device according to claim 17,
wherein the notch angle of each processing process is set to be shifted by a constant angle from that of another processing process.

19. The method for manufacturing a semiconductor device according to claim 17,
wherein the notch angles of the respective processing processes are randomly set for each processing process.

20. The method for manufacturing a semiconductor device according to claim 19,
wherein the notch angles of the respective processing process is randomly set for each processing process using a random number from 0 to 360.
